(19) United States
(12) Patent Application Publication
(10) Pub. No.: US 2008/0238462 A1
(43) Pub. Date: Oct. 2, 2008

(54) TEST DEVICE FOR SEMICONDUCTOR DEVICES

(75) Inventors: Udo Hartmann, Neuried (DE); Markus Kollwitz, Neubiberg (DE); Sascha Nerger, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/057,432

(22) Filed: Mar. 28, 2008

(30) Foreign Application Priority Data
Mar. 29, 2007 (DE) 10 2007 015 283.5

(51) Int. Cl. G01R 31/26; H01L 23/58

(52) U.S. Cl. 324/758; 257/48; 257/E23.079

(57) ABSTRACT

A test device for semiconductor devices is disclosed. One embodiment provides a probe card, having at least one contact test body for contacting a semiconductor device. The probe card includes self-alignment devices and/or a penetration restriction device, or parts thereof. A semiconductor device is provided having at least one contact field adapted to be contacted by contact test bodies of a test device. The semiconductor device includes self-alignment devices and/or a penetration restriction device, or parts thereof, for the contact test body in the region of the contact field.

### CROSS-REFERENCE TO RELATED APPLICATIONS

This Utility Patent Application claims priority to German Patent Application No. DE 10 2007 015 283.5 filed on Mar. 29, 2007, which is incorporated herein by reference.

### BACKGROUND

Aspects relate to a test device for semiconductor devices and to a pertinent semiconductor device and a pertinent wafer, to a system with a test device and with a semiconductor device or wafer, and to a method for testing semiconductor devices.

Semiconductor devices, e.g., integrated (e.g., analog or digital and/or mixed-signal) circuits, semiconductor memory devices such as, for instance, functional memory devices (PLAs, PALs, etc.) and table memory devices (e.g., ROMs and RAMs, for example, SRAMs and DRAMs), etc. are subject to comprehensive tests, e.g., in the semi-finished and/or finished state, at a plurality of test stations.

For testing the semiconductor devices, a semiconductor device test device may be present at the respective test station which generates the test signals required for testing the semiconductor devices.

For instance, at a first test station, the signals required for testing the semiconductor devices that are still available on the wafer may, for instance, be generated by a test device that is connected with a semiconductor device test card (“probe card”), and may be input in the respective contact fields of the semiconductor devices using needle-shaped connections (“contact needles”) provided at the test card.

The signals output by the semiconductor devices at contact fields in reaction to the input test signals are tapped by corresponding, needle-shaped connections (“contact needles” or “test needles”) of the probe card, and (e.g., via a signal line that connects the probe card with the test device) transmitted to the test device where an evaluation of the signals can take place.

After the sawing apart of the wafer, the devices, that are then available individually, can each be loaded individually in carriers (i.e. a package) and be transported further to a further test station.

At the further test station, the carriers are inserted in adapters or sockets, that are connected with a (further) test device, and then the device that is available in the respective carrier is subject to (further) test methods.

For testing the semiconductor devices available in the carriers, the test signals output by the test device are transmitted to the contact fields of the respective semiconductor device via the adapter and the carrier (or connections of the carrier, respectively).

The signals output by the semiconductor devices at contact fields in reaction to the input test signals are tapped by carrier connections and transmitted, via the adapter (and a signal line connecting the adapter with the test device), to the test device where an evaluation of the signals can take place.

Similarly, the semiconductor devices may, for instance, also be tested after their final incorporation in device packages (e.g., plug or surface-mountable packages), and/or after the incorporation of the packages, provided with semiconductor devices, in corresponding, electronic modules, etc.

Probe cards have to be manufactured with very high precision, so that they properly contact all the contact fields or pads during the contacting of the wafer. This has to be ensured under any usual specified conditions such as, for instance, for the entire active face of the probe card, and under the specified temperatures. This demands a very high manufacturing accuracy which partly also has an influence on the design of the chips or semiconductor devices. In addition, a high technical effort in the wafer prober is required for equipping the probe cards. Errors will result in a lower yield, e.g., by using contact field edge damages, contact problems, and damage to the contact fields by too deep penetration of the needle tip. For these and other reasons, there exists a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic representation of the basic structure of a semiconductor device test system used for testing semiconductor devices arranged on a wafer, including a probe card, and a test device connected thereto.

FIG. 2 illustrates a schematic representation in cross-sectional view of the basic structure of a system for testing semiconductor devices according to one embodiment in a first position.

FIG. 3 illustrates a schematic representation of the system of FIG. 2 in a second position.

FIG. 4 illustrates a schematic representation in cross-sectional view of the basic structure of a system for testing semiconductor devices according to one embodiment.

FIG. 5 illustrates a schematic detailed representation of a system for testing semiconductor devices according to one embodiment in cross-sectional view.

FIG. 6 illustrates a schematic representation in cross-sectional view of the basic structure of a system for testing semiconductor devices according to a fourth embodiment in a first position.

FIG. 7 illustrates a schematic representation of the system of FIG. 6 in a second position.

FIG. 8 illustrates a schematic representation of the basic structure of a system for testing wafers according to one embodiment.

FIG. 9 illustrates a schematic representation of the basic structure of the system of FIG. 8 in parts in a cross-sectional view.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One aspect provides a possibility for the simplified contacting of contact fields of semiconductor devices by appropriate test devices, which is, moreover, sufficiently precise, reliable, and gentle.

One embodiment includes a test device for semiconductor devices, for example, a probe card, including at least one contact test body for contacting a semiconductor device, wherein the probe card includes self-alignment device and/or a penetration restriction device, or parts thereof.

In one embodiment, at least one contact test body is a test needle.

In one embodiment, a contact test body is designed sufficiently elastically and/or suspended flexibly, e.g., by using a cardan suspension, a spring element, or an elastic, in one embodiment soft elastic, suspension.

In one embodiment, the contact test body includes at its tip at least one guide edge that is, in a particularly favorable manner, arranged at the outer edge region of the tip. In one embodiment, the guide edge is designed to be annularly circumferential, in one embodiment in the shape of a truncated cone.

In one embodiment, the contact test body includes at least one magnetic element, in one embodiment a permanent magnet and/or a switchable electromagnet. Then, the contact test body is suspended flexibly by using a cardan suspension or a spring element.

For restricting the depth of penetration and for the vertical positioning of the contact test body, it includes brim that is at least partially circumferential. Favorably, the brim is arranged at a side of the contact test body in the vicinity of a tip of the contact test body.

In one embodiment, the test device includes at least one guide element for aligning the test device at the wafer. This guide element is a pin that is aligned in one embodiment in approaching direction of the test device.

The above features may be implemented alone or in any combinations. The guide element may also include some or all features which the contact test body includes, e.g., guide edges, magnets, and/or brim(s).

A semiconductor device including at least one contact field that is adapted to be contacted by contact test bodies of a test device includes, in the region of the contact field, self-alignment device and/or a penetration restriction device, or parts thereof, for the contact test body.

The contact field is positioned in a depression of the semiconductor device, in one embodiment if the depression tapers in a funnel-shaped manner toward the contact field.

In one embodiment, a semiconductor device (chip or wafer) includes at least one magnetic element in the region of the contact field.

In one embodiment, the magnetic element is positioned directly at the contact field, in one embodiment at a side facing away from the contacting of the contact field. In another embodiment, the contact field is positioned in a depression of the semiconductor device, and at least one magnetic element is positioned at the semiconductor device at a side wall of the depression. Combinations as well as other or further positions of the magnetic elements are possible. One embodiment provides a semiconductor device in which the magnetic element includes at least one permanent magnet and/or electromagnet.

One embodiment provides a semiconductor device in which the contact field is positioned in a depression of the semiconductor device, wherein at least an aperture diameter of the depression is smaller than a pertinent diameter of a brim of a pertinent test body. One embodiment provides a semiconductor device in which the depression tapers in a funnel-shaped manner toward the contact field.

One embodiment provides a semiconductor device that includes a guide receptacle for receiving a guide element of the test device, in one embodiment a groove.

The object is also solved by a wafer with at least one chip, including at least one semiconductor device with at least one contact field that is adapted to be contacted by contact test bodies of a test device, wherein the wafer includes at least one guide receptacle for receiving a guide element of the test device, in one embodiment a groove. Of particular advantage is a design in which every chip or every semiconductor device to be individualized includes at least one guide receptacle, in one embodiment a groove. A groove or a plurality of grooves may also be provided externally of the chip, e.g., in edge regions of the wafer.

The object is also solved by systems of at least one of the above-mentioned test devices and at least one semiconductor device to be tested as described above, which are coordinated, i.e. include in one embodiment devices and counter devices for self-alignment and/or prevention of penetration, or are equipped for cooperation with same.

The object is also solved by a method for testing semiconductor devices by using a test device, in one embodiment a probe card, wherein at least one contact test body of the test device is contacted with a contact field of a semiconductor device. The method includes:

approaching the contact field by the test device; and

lateral aligning of the contact test body and/or the test device with respect to the semiconductor device by using self-alignment devices device at the contact test body and/or at the test device, at the semiconductor device or partially at the contact test body and partially at the semiconductor device and/or at the test device;

and/or the following:

approaching the contact field by the contact test body; and

putting the contact test body on the semiconductor device after contacting the contact field with a predetermined depth of penetration.

One embodiment is a method in which the process of the lateral aligning of the contact test body includes a mechanical centering of the contact test body at the semiconductor device during the introduction in a depression of the semiconductor device, wherein the contact field is positioned in the depression.

One embodiment is a method in which the process of the lateral aligning of the contact test body includes a centering of the contact test body by the interaction of electromagnetic fields, in one embodiment of magnetic fields, of the contact test body and the semiconductor device.

One embodiment is a method in which the centering of the contact test body includes an elastic deformation of the contact test body and/or a flexible deflection of the contact test body at the test device.

One embodiment is a method in which the process of the lateral aligning of the test device includes an introduction of at least one guide element, in one embodiment a guide pin, of the test device in a pertinent guide receptacle in the wafer, in one embodiment in a semiconductor device of the wafer.

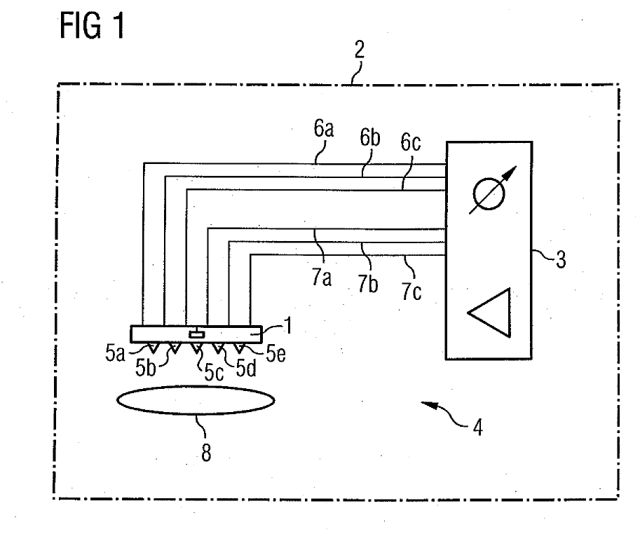

FIG. 1 illustrates a schematic representation of the basic structure of a semiconductor device test system 4, according to prior art, which is used at a test station 2 for testing semiconductor devices arranged or manufactured on a wafer 8.

The semiconductor devices to be tested which are still available on the wafer 8 (e.g., of silicon or another suitable semiconductor material such as GaAs) may, for instance, be integrated (analog, digital, and/or mixed-signal) circuits or single semiconductors, and/or semiconductor memory devices such as, for instance, functional memory devices (PLAs, PALs, etc.), or table memory devices (e.g., ROMs or RAMS), in one embodiment SRAMs or DRAMs, e.g., semiconductor devices using a clock frequency higher than 500 MHz, in one embodiment higher than 1 GHz (here e.g., DRAMs (Dynamic Random Access Memories or dynamic read-write memories) with double data rate (DDR−DRAMs=Double Data Rate, DRAMs)). The invention is, however, not restricted to a particular kind of semiconductors.

The test signals required for testing the semiconductor devices that are still available on the wafer 8 are transmitted by a test device 3 (here: a digital ATE test device) via one or a plurality of signal lines (“driver channels” 6a, 6b, 6c) to a semiconductor device test card or probe card 1 and, via contact needles 5a, 5b, 5c, 5d, 5e provided at the probe card, to contact fields (“pads”) provided on the semiconductor devices.

As results from FIG. 1, the contact needles 5a, 5b, 5c, 5d, 5e extend from the bottom of the probe card 1 downward in the direction of the wafer 8.

The signals output in reaction to the input test signals at semiconductor device connections or contact fields are, correspondingly inversely as described above, tapped by contact needles 5a, 5b, 5c, 5d, 5e of the probe card 1 and supplied, via one or a plurality of signal lines (“comparator channels” 7a, 7b, 7c) to the test device 3 where an evaluation of the signals can then take place. The driver channels and comparator channels may also be comprehended in joint input/output channels.

As results from FIG. 1, the above-mentioned probe card 1, the semiconductor devices to be tested (or the wafer 8 or on the wafer 8, respectively), and possibly also the above-mentioned test device 3 are arranged at the test station 2 in a subsystem secluded from the environment (e.g., a micro clean room system).

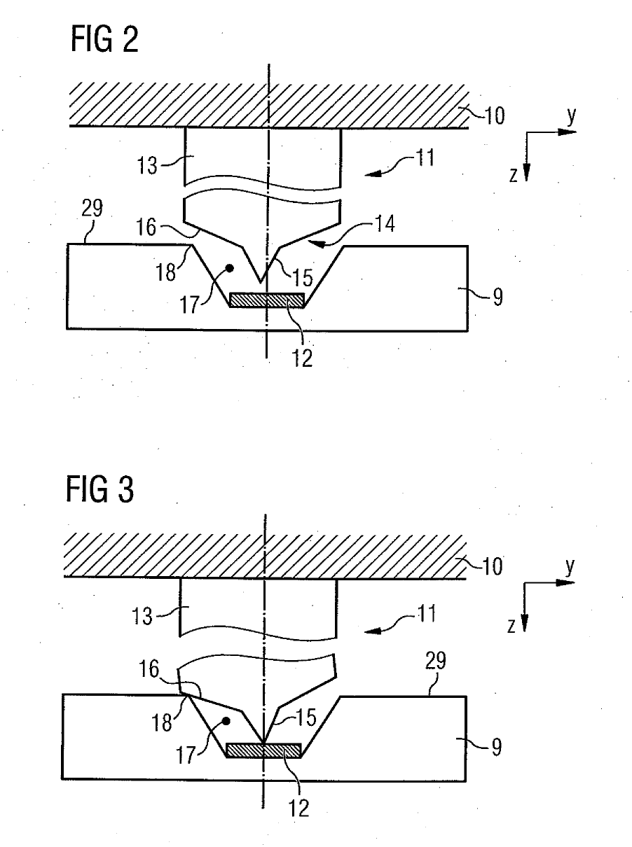

FIG. 2 illustrates in cross-sectional view a test device for testing semiconductor devices 9 by using a probe card 10. At the bottom of the probe card 10, a contact test body in the form of a test needle 11 that is illustrated by way of example here is arranged for contacting a contact field 12 of the semiconductor device 9. The test needle 11 includes a test needle body 13 and a front-side test needle tip 14. The test needle tip 14 includes a contact tip 15 and a circumferential, chamfered guide edge 16 tapering toward the semiconductor device 9 at the outer edge region of the test needle tip 14.

The semiconductor device 9 includes in the region of the contact field 12 a depression 17 in the semiconductor device with respect to a surface 29 of same, at the bottom of which the contact field 12 is positioned. The depression 17 tapers in a funnel-shaped manner from a depression aperture at the level of the edges 18 at the surface 29 of the semiconductor device 9 toward the contact field 12. The side walls of the depression 17 and the guide edge 16 thus have a similar shape in the form of a funnel or a truncated cone, in which, however, the angle of aperture of the funnel may, for instance, be different. The diameter of aperture of the depression 17, which depends on an angular position in a plane perpendicular to the z-axis, is smaller than the outer diameter of the guide edge 16.

The guide edge 16 of the test needle tip 14 forms, along with the depression 17 or its aperture edge 18, respectively, self-alignment devices, as will be explained in more detail in the following by using FIGS. 2 and 3.

Prior to approaching the contact test body 11 to the contact field (“pad”) 12, as is indicated in FIG. 2, the test needle tip 14 and thus the contact tip 15 may be laterally staggered with respect to the contact field 12, i.e. here: in y-direction. This maladjustment may be more pronounced in reality and result, for instance, in contact field edge damages or contact problems.

On approaching the contact test body 11 to the contact field 12 in z-direction, the left region of the guide edge 16 as illustrated in FIG. 3 contacts the aperture edge 18 of the depression 17. By the inclined design of the guide edge 16, a force is exerted on the test needle 11 in the direction of the middle of the contact field 12, which is indicated by the dot and dash line. Thus, the contact test body 11 or the contact tip 15, respectively, is shifted relative to the contact field 12 and thus at least partially centered (“aligning”). This shifting is enabled in that the test needle 11 is designed to be sufficiently elastic and/or is suspended flexibly at the probe card 10, for instance, by using a cardan suspension, a spring, or an elastic intermediate element (not illustrated). A slight inclination of the test needle 11 is harmless with the usually large needle lengths (in z-direction).

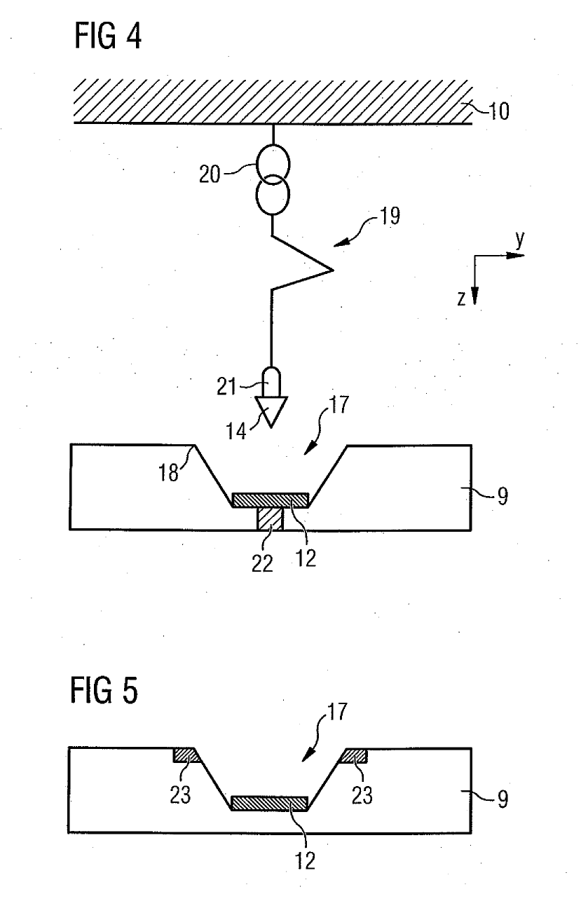

FIG. 4 illustrates a further embodiment of an exemplary test needle 19 that is fixed to a probe card 10, which is now linked with the remaining probe card 10 by using a cardan suspension 20. Above the test needle tip 14, a magnetic element 21 is positioned for generating an electromagnetic field with a magnetic effect, in one embodiment a magnetic field. The magnetic element 21 may include one or a plurality of permanent magnets or controllably switchable electromagnets.

The semiconductor device 9 or the wafer including the semiconductor device 9, respectively, is of similar design as compared to the embodiment of FIGS. 2 and 3, except that it now includes a magnetic counter element 22 below the contact field 12.

Already by just one of the magnets 21, 22, self-alignment devices would be provided if the opposite test needle 19 or the contact field includes paramagnetic materials such that a sufficient force can be generated for a lateral shifting of the test needle 19 toward the contact field 12. As illustrated in FIG. 4 it is, however, of advantage for applying a larger lateral force if both the test needle 19 and the semiconductor device 9 include magnets 21, 22 in the region of the contact field 12 which attract each other in the instant example. To this end, the suspension 20 of the test needle 19 has to be flexible enough that its sufficient deflection is enabled. By the magnetic attraction it is possible to center the test needle 19 toward the contact field 12 at least partially.

In one embodiment, any other suitable flexible linking may be used instead of the cardan suspension 20, e.g., a spring or another elastic element, e.g., an elastic plastic solid body or a thin metallic interface.

Mixed forms of self-alignment devices are also possible: thus, the test tip 14 may be designed as illustrated in FIGS. 2 and 3. This facilitates centering also for larger maladjustments.

FIG. 5 illustrates a further embodiment of the semiconductor device 9 or of the wafer, respectively, in which a magnetic (counter) element 23 is arranged circumferentially at the upper edge of the depression 17. This magnetic element 23 may be designed to be attractive for interaction with the test needle. In one embodiment, if a magnetic element is used at the test body, as is, for instance, illustrated in FIG. 4, the magnets of the test body and of the semiconductor device may be designed to repel each other.

Mixed forms of the semiconductor device of a combination of the embodiments according to FIGS. 4 and 5 are also possible.

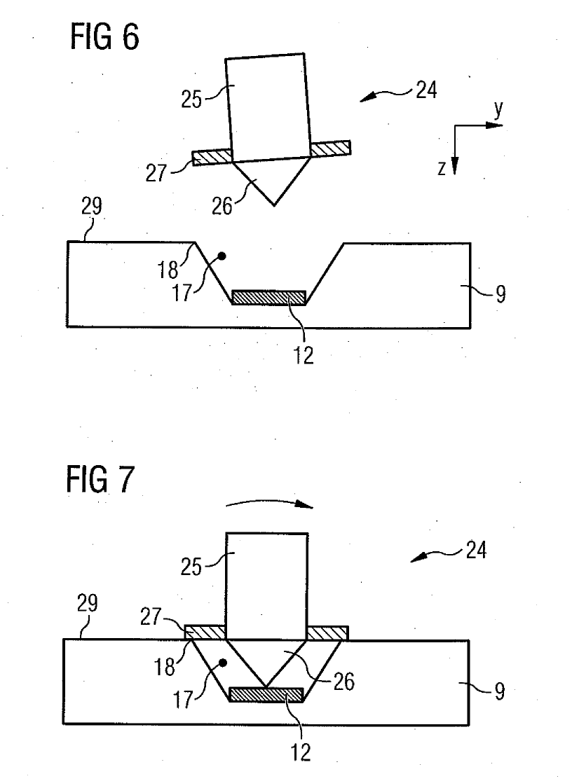

FIGS. 6 and 7 illustrate in cross-sectional view a further embodiment of a system for testing semiconductor devices in a first, lifted position (FIG. 6) and a second, contacting position (FIG. 7).

In FIG. 6, a test needle 24 includes a longitudinal test needle body 25 and a test needle tip 26, wherein a laterally extending brim 27 is positioned circumferentially at the circumference of the test needle body 25 directly above the tip 26. The test needle 24 is drawn schematically with a tilt with respect to the z-axis. The semiconductor device 9 is designed similar to that in FIGS. 2 and 3, wherein a diameter of the upper edge 18 of the depression 17 is smaller than the diameter of the brim 27.

On approaching the semiconductor device 9 or the wafer, respectively, along the z-axis, the inclined test needle 24 first of all contacts the surface 29 of the semiconductor device 9 with the edge that is at the left in FIGS. 6 and 7, and is turned to the vertical by the test needle 24 continuing to move toward the semiconductor device 9, as is indicated by the arrow in FIG. 7. To this end, the test needle 24 is designed to be sufficiently elastic and/or suspended in a sufficiently flexible manner. After reaching the vertical (parallel to the z-axis), the test needle 24 contacts the surface 29 also with the side that is at the right in this Figure, so that the vertical positioning is finished. The brim 27 may be designed to be completely circumferential or, in an alternative embodiment, be, for instance, constructed of sectors that are staggered angularly in the x-y plane (not illustrated).

By using the brim it is thus possible to firstly achieve the vertical positioning and thus the alignment of the test needle tip 26 with respect to the contact field 12. Additionally, it is possible to adjust the depth of penetration of the test needle tip 26 in the contact field 12 and to thus prevent that it penetrates too deeply and damages the contact field. The depth of penetration may be adjusted or modified by a variation of the shape of the brim and/or the shape of the depression, as well as by a suitable choice of material, e.g., a passivation.

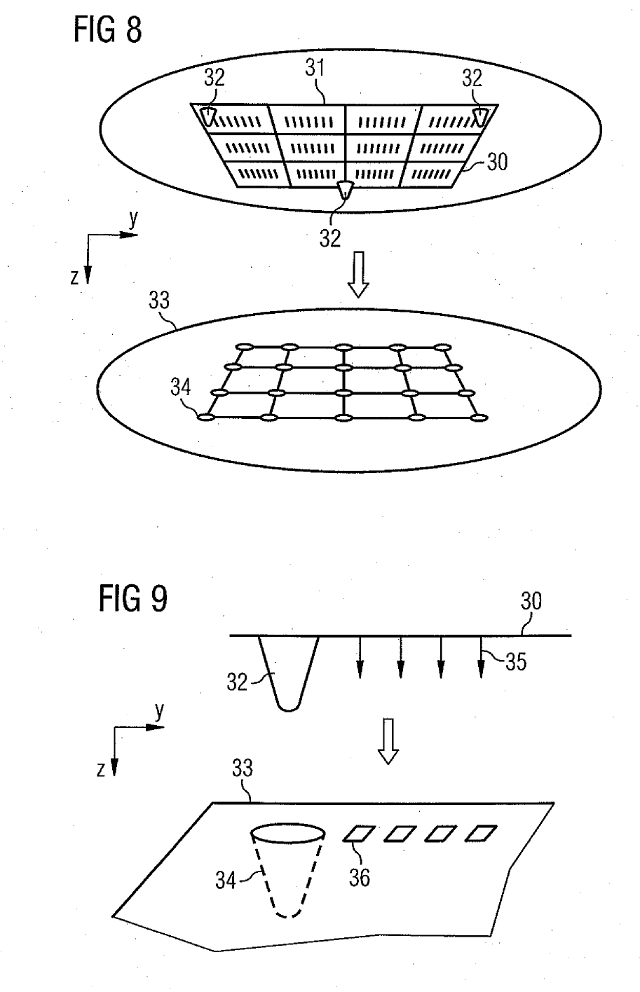

FIG. 8 illustrates, in side view, a bottom of a probe card 30 with test needles arrange thereon and indicated as small dashes, which are comprehended in probe card (partial) fields 31, each of which is provided for testing a semiconductor device or chip (without illustration) on a wafer 33. A plurality of, here: three, guide elements in the form of guide pins 32 are arranged at the probe card 30.

The probe card 30 is spaced apart from the wafer 33 in z-direction. For testing the wafer 33, the probe card 30 is moved on the wafer 33 in z-direction, wherein the test needles should contact the pertinent contact fields. The wafer 33 includes a plurality of guide receptacles in the form of grooves 34 which are suited to receive one of the guide elements 32. Every chip (not illustrated) includes one of the—elliptically drawn, grooves 34. By the arrangement of grooves 34 on every chip it is possible to contact in a variable manner.

FIG. 9 illustrates the configuration of FIG. 8 in more detail in a lateral cross-sectional view. The wafer 33 includes the guide receptacle in the form of a groove 34 suited for receiving one of the guide pins 32. By aligning the probe card 30 and the wafer 33 relative to each other by using the fitting of the guide pin or the guide pins 32 in the selected groove or the selected grooves 34, it is possible to achieve a large-space alignment of the test needles 35 relative to pertinent contact fields 36 on the wafer 33.

The respective guide elements 32 and guide receptacles 34 may, for simplified and precise alignment, include the same or similar features as the test needles or depressions in FIGS. 2 to 7, namely, for instance, guide edges at the guide element and inclined side walls at the groove; magnets at the guide element and/or at the groove; broad brims at the guide element; or a combination thereof.

Of course, the invention is not restricted to the above embodiments, but may, for instance, include different modifications and combinations.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A test device for semiconductor devices, comprising:
at least one contact test body for contacting a semiconductor device;
wherein the test device comprises means for self-alignment and/or a penetration restriction device, or parts thereof.

2. The test device of claim 1, wherein at least one contact test body is a test needle.

3. The test device of claim 1, wherein a contact test body is designed elastically and/or suspended flexibly.

4. The test device of claim 1, wherein the contact test body comprises at least one guide edge at its tip.

5. The test device of claim 4, wherein the guide edge is formed at the outer edge region of the tip and the guide edge is designed annularly circumferentially in the shape of a truncated cone.

6. The test device of claim 1, wherein the contact test body comprises at least one magnetic element, the magnetic element comprising at least one permanent magnet and/or one electromagnet.

7. The test device of claim 6, wherein the contact test body is flexibly suspended by using a cardan suspension or a spring element.

8. The test device of claim 1, wherein the contact test body comprises a brim that is at least partially circumferential, wherein the brim is arranged at a side of the contact test body in the vicinity of a tip of the contact test body.

9. The test device according to claim 1, comprising at least one guide element for aligning the test device at the wafer, wherein the guide element is a pin that is aligned in particular in approaching direction of the test device.

10. A semiconductor device comprising:
at least one contact field adapted to be contacted by contact test bodies of a test device;
wherein the semiconductor device comprises, in the region of the contact field, means for self-alignment and/or a penetration restriction device, or parts thereof, for the contact test body.

11. The semiconductor device of claim 10 for the contacting by a test device, wherein the contact field is positioned in a depression of the semiconductor device.

12. The semiconductor device of claim 11, wherein the depression tapers in a funnel-shaped manner toward the contact field.

13. The semiconductor device of claim 10 for the contacting by a test device, wherein at least one magnetic element is arranged in the region of the contact field, and wherein at least one magnetic element is positioned directly at the contact field at a side facing away from the contacting of the contact field.

14. The semiconductor device of claim 13, wherein the contact field is positioned in a depression of the semiconductor device, and wherein at least one magnetic element is positioned at the semiconductor device at a side wall of the depression, and wherein the magnetic element comprises at least one permanent magnet and/or electromagnet.

15. The semiconductor device of claim 10 for the contacting by a test device, wherein the contact field is positioned in a depression of the semiconductor device, wherein at least an aperture diameter of the depression is smaller than a pertinent diameter of the brim, and wherein the depression tapers in a funnel-shaped manner toward the contact field.

16. The semiconductor device of claim 10 for the contacting by a test device comprising a guide receptacle for receiving the guide element of the test device, wherein the guide receptacle comprises a groove.

17. A system with a test device comprising:
at least one contact test body for contacting a semiconductor device, wherein the test device comprises means for self-alignment; and
at least one contact field adapted to be contacted by contact test body of a test device, wherein the semiconductor device comprises, in the region of the contact field, means for self-alignment for the contact test body.

18. The system with a test device of claim 17:
wherein the contact test body has at least on guide edge at its tip; and
wherein the contact field is positioned in a depression of the semiconductor device.

19. The system with a test device of claim 17:
wherein the contact test body comprises at least one magnetic element; and
wherein at least one magnetic element is arranged in the region of the contact field.

20. The system with a test device of claim 17:
wherein the contact test body comprises a brim that is at least partially circumferential; and
wherein the contact field is positioned in a depression of the semiconductor device, wherein at least an aperture diameter of the depression is smaller than a pertinent diameter of the brim, and wherein the depression tapers in a funnel-shaped manner toward the contact field.

21. The system with a test device of claim 17 comprising:
at least one guide element for aligning the test device at the wafer; and
a guide receptacle for receiving the guide element of the test device.

22. A wafer comprising:
at least one semiconductor device with at least one contact field adapted to be contacted by contact test bodies of a test device;
wherein the wafer comprises at least one guide receptacle for receiving a guide element of the test device; and
wherein the guide receptacle comprises a groove.

23. A method for testing semiconductor devices using a test device, wherein at least one contact test body of the test device is contacted with a contact field of a semiconductor device, the method comprising:
approaching the contact field by the test device; and
laterally aligning the contact test body and/or the test device with respect to the semiconductor device using self-alignment means at the contact test body and/or at the test device at the semiconductor device or partially at the contact test body and partially at the semiconductor device and/or at the test device;
and/or comprising:
approaching the contact field by the contact test body; and
putting the contact test body on the semiconductor device after contacting the contact field with a predetermined depth of penetration.

24. The method of claim 23, wherein the lateral aligning of the contact test body comprises one of the group of processes comprising a mechanical centering of the contact test body at the semiconductor device on introduction in a depression of the semiconductor device, wherein the contact field is positioned in the depression, and a centering of the contact test body by the interaction of electromagnetic fields of the contact test body, and of the semiconductor device.

25. The method of claim 24, wherein the centering of the contact test body comprises an elastic deformation of the contact test body and/or a flexible deflection of the contact test body at the test device and, wherein the lateral aligning of the test device comprises the introducing of at least one guide element, in particular a guide pin, of the test device in a pertinent guide receptacle in the wafer, in particular in a semiconductor device of the wafer.
